(19) United States
(12) Patent Application Publication
(10) Pub. No.: US 2022/0270658 A1
(43) Pub. Date: Aug. 25, 2022

(54) Device for Data Storage and Processing, and Method Thereof

(71) Applicants: Politecnico di Torino, Torino (TO) (IT); Universita Degli Studi Di Roma Tor Vergata, Roma (IT)

(72) Inventors: Fabrizio Riente, Verres (IT); Marco Ottavi, Roma (IT); Marco Vacca, Torino (IT); Giovanna Turvani, Torino (IT)

(21) Appl. No.: 17/631,156

(22) PCT Filed: Jun. 23, 2020
(86) PCT No.: PCT/IB2020/055919

§ 371 Date: Jan. 28, 2022

(30) Foreign Application Priority Data
Jul. 31, 2019 (IT) 102019000013542

(51) Int. Cl. G11C 11/16; H03K 19/20; G11C 19/08

(52) U.S. Cl. CPC G11C 11/161; H03K 19/20; G11C 11/1675; G11C 19/0841

(57) ABSTRACT

A device for data storage and processing includes: at least two input racetrack elements having a plurality of first magnetization regions; at least one output racetrack element having a plurality of second magnetization regions, wherein a magnetization vector is adapted to switch from a first direction to the opposite one, or vice versa, by way of a magnetic field of reduced intensity compared with a magnetic field required to produce a similar switching of a magnetization vector of the first magnetization region, wherein the input racetrack elements and output racetrack element are configured in such a way as to constitute at least one elementary logic gate, wherein at least two of the first magnetization regions are magnetically coupled to at least one of the second magnetization regions.

### BACKGROUND OF THE INVENTION

### 1. The Field of the Invention

The present invention relates to a device for data storage and processing, in accordance with the preamble of claim 1. In particular, the present invention relates to a device capable of operating both as a storage device and as a processing device for processing data stored therein, as well as to a method of operation thereof.

The field of application of the present invention is digital electronics, e.g., devices such as smartphones, computers, television sets, etc. The invention can be used as an advanced memory system, replacing the current main and/or cache memories of such devices. The subject of the present invention can also be used for all those applications, e.g., big data, which require high computation parallelism and a high number of bitwise elementary operations, such as AND, OR, NAND, NOR, and so forth.

### 2. The Relevant Technology

The means currently employed for storing digital information for computer applications are random access memories (RAM) and solid state disk (SSD) or magnetic disk (HDD) units: these classes of devices are evolving at an increasing rate. HDDs are inherently very slow, with typical access times of several milliseconds, because of the mass of the revolving disk; RAMs are faster and more reliable than HDDs, but the cost incurred for storing a single data bit into an HDD is still about a hundred times lower than that required by a RAM.

United States patent U.S. Pat. No. 6,834,005 describes a new class of potential non-volatile memories, called racetrack memories. These memories are based on controlled shifting of a series of domain walls along nanowires of ferromagnetic material, which utilize spin-polarized current pulses. Racetrack memories may be fabricated by using either in-plane magnetization materials or out-of-plane magnetization materials. This latter type of magnetization permits the fabrication of low-consumption, high-density memories, thus making racetrack memories accessible for mass usage.

A prototype of a racetrack memory integrated with a CMOS circuit, created by using a 90 nm technological process, has been presented by A. J. Annunziata, M. Gaidis and L. Thomas in the article entitled “Racetrack memory cell array with integrated magnetic tunnel junction readout”, published at the International Electron Devices Meeting (12/2011).

Racetrack memories have been recently used also as a basic element for non-volatile CMOS hybrid logic circuits, as proposed by K. Huang and R. Zhao in the article entitled “Magnetic domain-wall racetrack memory-based nonvolatile logic for low-power computing and fast runtime reconfiguration”, published by IEEE Transactions on Very Large Scale Integration (VLSI-2016).

The storage systems based on racetrack memories known in the art suffer from a number of drawbacks, which will be illustrated below.

A first drawback is related to the fact that the systems known in the art do not allow processing the stored data directly within the memory cells. Usually the data that need to be processed are moved outside the array of memory cells via connections (data lines) and, after having been processed, are stored again within the array of memory cells. The circuits implementing the additional logic functions are located near the array of memory cells, so as to limit the data transfer and reduce the length of the interconnections. Therefore, the data are not actually processed within the memory cells.

Another drawback is related to the introduction of data processing delays caused by the movement of the data along the connection lines between the memory cells and the circuits that implement the data processing logic functions; this necessarily implies a reduction in the performance of the electronic devices that employ such storage systems.

A further drawback comes from the fact that such storage systems do not permit a high level of data processing parallelism because of the limited number of connections between the memory cells and the circuits that implement the data processing logic functions.

### SUMMARY OF THE INVENTION

It is one object of the present invention, therefore, to solve these and other problems, and particularly to provide a racetrack memory-based device and a method for data storage and processing which utilize a logic paradigm internal to the memory cells, thereby overcoming the bottleneck of Von Neumann's computational machines.

It is another object of the present invention to provide a device and a method for data storage and processing which ensure high data processing parallelism.

It is a further object of the present invention to provide a device and a method for data storage and processing which ensure a low energy consumption.

It is yet another object of the present invention to provide a device and a method for data storage and processing which permit the implementation of fully magnetic or transistor-based hybrid circuits.

The invention described herein consists of a novel magnetic memory of the non-volatile racetrack type, which can execute elementary logic functions directly on the stored data. The device according to the invention implements functions that a racetrack memory known in the art is not able to execute. Logic operations can be executed in parallel on all the data stored therein, without requiring the use of any additional circuits. The data can be moved in one direction and read/written by using external elements.

The article presented by M. Vacca, M. Graziano and M. Ottavi, entitled “Racetrack Logic”, published in Electronics Letters, vol. 53, 22. pp. 1462-1464, 2017, describes the implementation of logic operations for racetrack memories fabricated from materials having in-plane magnetization. The type of logic operation described in the above-mentioned article differs from the present invention: the solution presented in the article allows for punctual execution of elementary logic operations on the stored data by means of two magnets, whereas the present invention makes it possible to carry out parallel calculations within the structure without using any magnet.

Further advantageous features of the present invention are set out in the appended claims, which are an integral part of the present description.

### BRIEF DESCRIPTION OF THE DRAWINGS

The invention will now be described in detail by means of some non-limiting embodiments with particular reference to the annexed drawings, wherein:

FIG. 1 schematically shows an example of a prior-art racetrack memory;

FIG. 2 schematically shows a device for data storage and processing according to an embodiment of the present invention;

FIG. 3a schematically shows an elementary logic gate of the device of FIG. 2;

FIG. 3b shows a truth table of the elementary logic gate of FIG. 3a;

FIG. 3c schematically shows a geometry of the elementary logic gate of the device of FIG. 2;

FIG. 4 shows an exemplary flow chart of a method for data storage and processing of the device of FIG. 2.

### DETAILED DESCRIPTION OF THE PREFERRED EMBODIMENTS

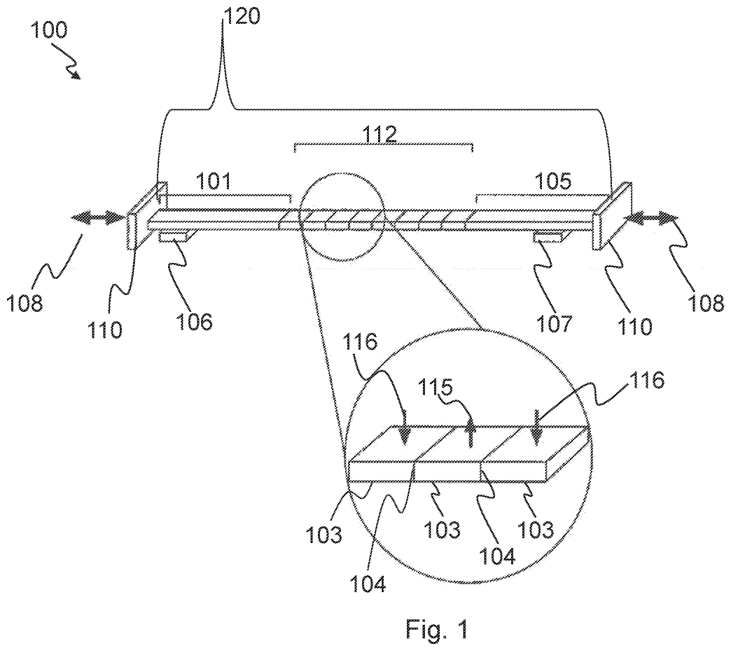

With reference to FIG. 1, there is schematically shown an explanatory embodiment of a racetrack memory 100 currently known in the art. In a memory of the racetrack type, information is stored in the form of magnetization of a track made of ferromagnetic material. Typically, said ferromagnetic track has a length of the order of some tens of micrometers and a width and a thickness of the order of some tens of nanometers. The ferromagnetic materials employed for these types of devices are, for example, iron, cobalt and/or nickel alloys with crystalline grids that characterize the inherent magnetic properties of the ferromagnetic material, such as, for example, its magnetocrystalline anisotropy. The binary information is encoded by means of two stable magnetization values that the material can assume locally. The magnetization vector may be either parallel (in-plane) or perpendicular (out-of-plane) to the direction of greatest extension of the ferromagnetic track, and is typically housed on a supporting plane along the direction of greatest extension of the ferromagnetic track.

The region of the ferromagnetic track where a transition occurs between two magnetization values is called domain wall. Different types of domain walls may exist, depending on the geometric shape and dimensions of the ferromagnetic track. For example, domain walls may be of the transverse-wall or vortex-wall type for in-plane magnetizations, or of the Neel-wall or Bloch-wall type for out-of-plane magnetizations.

The magnetic information stored in the racetrack can be moved to the right or to the left along the ferromagnetic track by means of a spin-polarized electric current flowing through the magnetic track itself. The angular moment associated with the spin-polarized electric current is transferred to the domain wall by means of the spin-moment transfer phenomenon, thus causing it to move in the direction of the current. The structure may be considered as a magnetic shift register in which the data are moved along the direction of greatest extension of the racetrack, so as to intercept the data read/write elements.

For example, a racetrack memory may comprise at least one racetrack element 100, shown in FIG. 1, and comprises a memory element 120, a write element 106, a read element 107, and at least two electric contacts 110 at the ends of the memory element 120, so that a spin-polarized electric current 108 can flow across them.

The memory element 120 consists of a ferromagnetic track comprising a data storage region 112, an upper (left) reservoir 101, a lower (right) reservoir 105. The size of the upper reservoir 101 and lower reservoir 105 is such as to contain the entire data storage region 112.

The data storage region 112 comprises a plurality of first magnetization regions (or domains) 103 arranged in succession, where magnetization is stable. Depending on the type of binary encoding in use, the information may be represented, for example, by the direction of the magnetization vector of each first magnetization region 103. The magnetization within each domain may point in any direction; for example, each first magnetization region 103 may have an out-of-plane magnetization, with the respective magnetization vectors pointing in opposite directions. By convention, the binary value “1” may be represented by the magnetization vector pointing in a first direction 115, e.g., up, while the binary value “0” may be represented by the magnetization vector pointing in the opposite direction 116, e.g., down. In the magnified view of FIG. 1 it is possible to see a series of domain walls 104, delimiting said first magnetization regions 103, with different magnetization vectors.

The spin-polarized electric current 108 is used in order to control the movements of the data within the memory element 120. The spin-polarized electric current 108 is generated, for example, by allowing a non-polarized electric current to flow through a magnetic domain having a given magnetization: in this manner, the non-polarized electric current assumes a spin polarization. The spin-polarized electric current 108 interacts with the domain walls 104, to which it applies a torque which, de facto, transports the domain wall 104 in the flowing direction of the spin-polarized electric current 108. The propagation speeds of the domain walls 104 typically vary from one hundred meters per second to several hundreds meters per second. The spin-polarized electric current 108 is typically applied by means of sequential pulses. Each pulse lasts as long as necessary for shifting the information by one position in the direction of the current flow. The direction of the spin-polarized electric current 108 defines the direction in which the domain walls 104 are shifted.

New data can be written to the racetrack element 100 by means of the write element 106 and can be read by means of the read element 107, both of which are located in proximity to the memory element 120, thus executing the read and write operations of said memory element 120. The write element 106 can write the information into the first magnetization region 103, e.g., through the spin-moment transfer effect, the latter being derived from an induced current generated by the write element 106. The read element 107 can read the information stored in the first magnetization region 103, e.g., through the magnetoresistive effect of a junction between two ferromagnetic materials separated by a thin oxide layer, in which junction the magnetic tunnel effect occurs.

The cross-sections of the first magnetization regions 103 of the racetrack element 100 may have such shapes and dimensions that allow shifting the domain walls 104, by applying a spin-polarized current 108, while giving the domain walls 104 adequate thermal stability. For example, the first magnetization regions 103 may have a rectangular, cylindrical, elliptical, square, etc. cross-section.

In order to increase thermal stability and define the spacing between the domain walls 104, pinning sites are introduced which add a potential barrier for the domain wall 104. Such pinning sites can be obtained, for example, by modelling notches along the edges of the ferromagnetic track or by modulating the cross-section thereof. Pinning sites also increase the stability of the domain walls 104 against external perturbations, such as, for example, fluctuations of external magnetic fields.

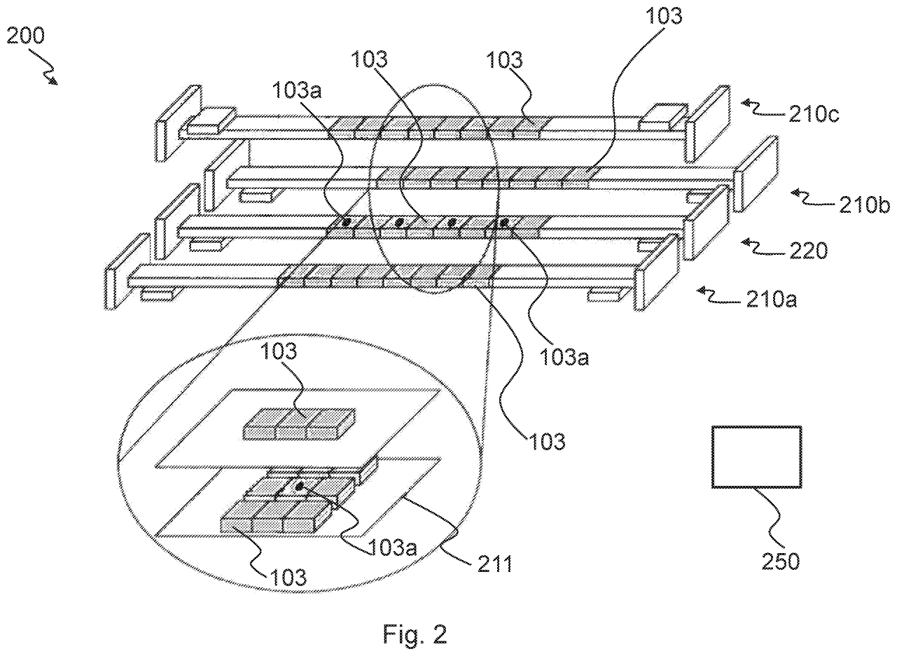

FIG. 2 schematically shows a device 200 for data storage and processing according to an embodiment of the present invention. Said device 200 comprises at least two input racetrack elements 210a, 210b, 210c and at least one output racetrack element 220. Each input racetrack element 210a, 210b, 210c and output racetrack element 220 comprises one memory element, at least one write element, at least one read element, and at least two electric contacts located at the ends of the memory element, so that a spin-polarized electric current can flow across them. In other embodiments of the invention, additional read/write elements may be used for each input racetrack element 210a, 210b, 210c and output racetrack element 220.

The input racetrack elements 210a, 210b, 210c allow for internal storage of data, so that such data are not alterable following the processing of the data stored in said device 200, e.g., performed by means of binary logic operations. The input racetrack elements 210a, 210b, 210c may be, for example, the racetrack elements 100 previously described with reference to FIG. 1. Each input racetrack element 210a, 210b, 210c can be controlled independently, so that the information contained therein will be shifted either in one direction or in the opposite direction according to the direction of the spin-polarized electric current 108 flowing along each input racetrack element 210a, 210b, 210c.

The output racetrack elements 220 allow for internal storage of data, so that such data are alterable following the processing of the data stored in said device 200, e.g., performed by means of binary logic operations. The output racetrack elements 220 may be, for example, the above-described racetrack elements 100, for which a plurality of first magnetization regions 103 are altered to change their ferromagnetic properties and thereby process the data stored in said device 200. For example, at least one first magnetization region 103 having out-of-plane magnetization vectors, with high crystalline anisotropy, may be irradiated, during the fabrication process, with a beam of gallium (Ga⁺) or helium (He) ions. This will result in degradation of the crystalline structure of the irradiated ferromagnetic material and a local reduction in its crystalline anisotropy, thus generating a second magnetization region 103a with altered ferromagnetic properties compared with the first magnetization region 103. In particular, the destructive irradiation of the crystalline structure of the ferromagnetic material creates a second magnetization region 103a that replaces the first magnetization region 103, in which the magnetization vector is adapted to switch from the first direction 115 to the opposite one 116, or vice versa, by means of a magnetic field of reduced intensity compared with the magnetic field required to produce a similar switching of a magnetization vector of the first magnetization region 103. This results in domain-wall nucleation in the second magnetization region 103a; for this reason, this region is called artificial nucleation center.

The input racetrack elements 210a, 210b, 210c and the output racetrack elements 220 are adapted to constitute at least one elementary logic gate, preferably a plurality of elementary logic gates, wherein at least two of said first magnetization regions 103 are magnetically coupled to at least one of said second magnetization regions 103a. Nucleation of the domain wall, and hence the switching of the magnetization vector from the stored logic value to its opposite, occur on the basis of the magnetic coupling, e.g., by adding up different magnetization contributions of one or more of said first magnetization regions 103 located in proximity to at least one second magnetization region 103a.

According to the present embodiment of the invention, three input racetrack elements 210a, 210b and 210c and one output racetrack element 220 are configured in such a way as to constitute at least one elementary logic gate of the device 200, i.e.: an output racetrack element 220 is interposed between a first input racetrack element 210a and a second input racetrack element 210b, arranged on a first supporting plane 211, while a third input racetrack element 210c is positioned over the output racetrack element 220.

Other embodiments of the invention may be obtained by arranging the input 210a, 210b, 210c and output 220 racetrack elements according to different configurations, e.g., by arranging one or more input racetrack elements 210a, 210b, 210c in alternate planes transversally to one or more output racetrack elements 220.

Said device 200 comprises a control unit 250 adapted to properly control the input racetrack elements 210a, 210b and 210c and the output racetrack element 220 in order to execute all the operations necessary for writing, reading and processing the data within said device 200, such as, for example, controlling the spin-polarized electric currents, activating the read/write elements, and so forth. The control unit 250 may be implemented, for example, as a logic circuit integrated into the device 200.

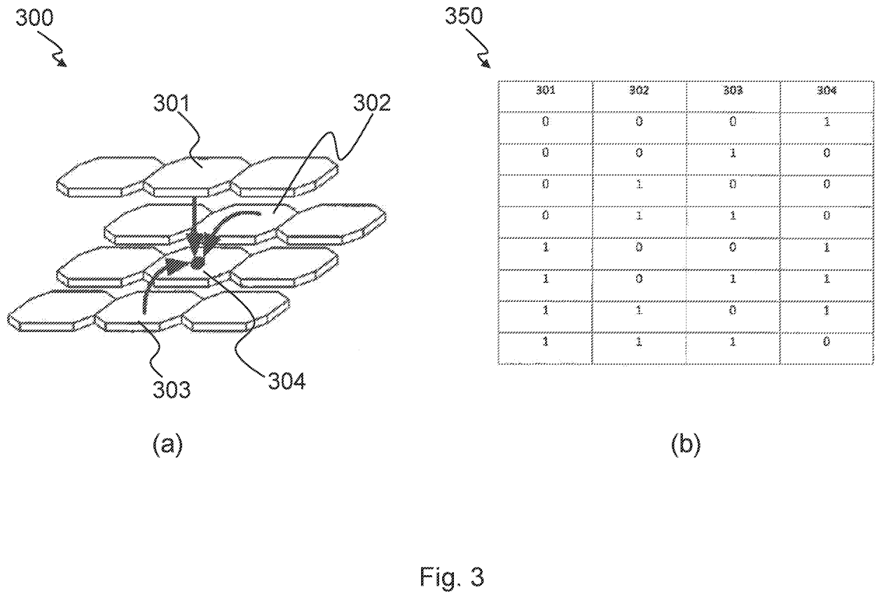

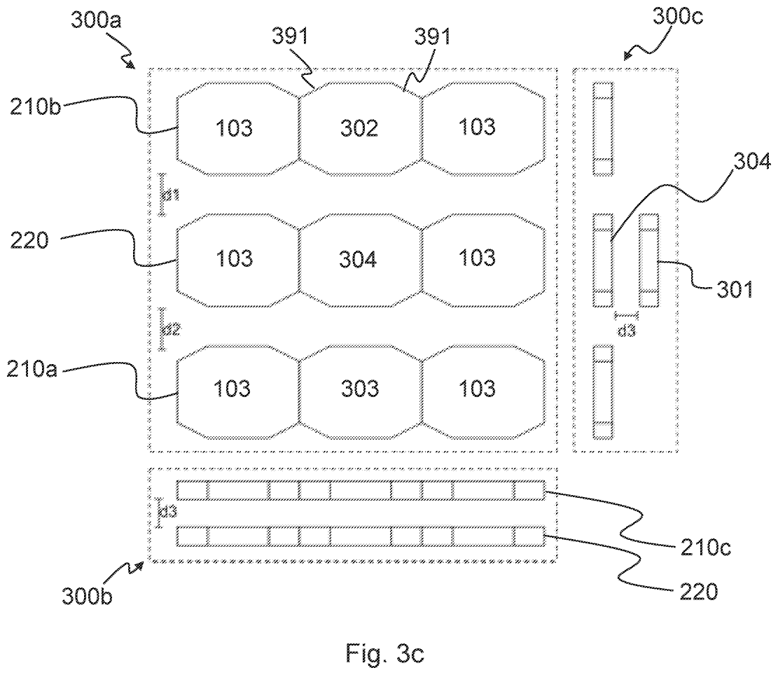

FIG. 3a schematically shows an elementary logic gate 300 with reference to the device of FIG. 2. According to the present embodiment of the invention, said elementary logic gate 300 comprises a first input magnetization region 301, a second input magnetization region 302 and a third input magnetization region 303, for which the respective magnetization vectors represent input binary information of said elementary logic gate 300. Said elementary logic gate 300 comprises an output magnetization region 304, the magnetization vector of which represents the output binary information of said elementary logic gate 300.

Said first magnetization regions 103 comprised in said input racetrack elements 210a, 210b and 210c correspond to said first, second and third input magnetization regions 301, 302 and 303, respectively, while said second magnetization region 103a comprised in the output racetrack element 220 corresponds to the output magnetization region 304. Such correspondences are defined on the basis of a predefined magnetic coupling scheme, considering, for example, the first magnetization regions 103 adjacent to (or neighbouring on) the second magnetization region 103a.

The magnetization vector of the output magnetization region 304 depends on the magnetic coupling of the magnetization vectors of the first, second and third input magnetization regions 301, 302 and 303, respectively. Such magnetic coupling may vary as a function of the relative positions between the output magnetization region 304 and the first, second and third input magnetization regions 301, 302 and 303, respectively. For example, the magnetization vectors of the second and third input regions 302 and 303 determine, respectively, an antiparallel coupling with the output magnetization region 304, whereas the magnetization vector of the first input region 301 determines a parallel coupling with the output magnetization region 304. In particular, the coupling with the output magnetization region 304 is of the antiparallel type when the input magnetization region lies in the same plane. Alternatively, the coupling is parallel when an input region is positioned over or under the output magnetization region 304.

In the present embodiment of the invention, the switching of the magnetization vector from a logic value to its opposite in the output magnetization region 304 is obtained by adding up the contribution of each magnetization vector of the first, second and third input magnetization regions 301, 302 and 303, respectively. The switching of the magnetization vector from a logic value to its opposite in the output magnetization region 304 can be triggered by a magnetic coupling contribution of a suitably generated external magnetic field Hₑₓₜ. If the resulting magnetic coupling contribution in the output magnetization region 304 exceeds a predefined critical value H_{c}, then domain-wall nucleation will occur; otherwise, the switching of the magnetization vector from a logic value to its opposite will not occur. In the present embodiment of the invention, each input magnetization region 301, 302 and 303 provides substantially the same coupling contribution in the output magnetization region 304. By appropriately sizing the magnetization regions comprised in said input racetrack elements 210a, 210b and 210c, it is possible to obtain substantially the same coupling contribution at the artificial nucleation center 304 for the input magnetization regions 301, 302 and 303 only, while substantially cancelling the contribution of the other neighbouring magnetization regions. FIG. 3c schematically shows a top view 300a and, respectively, first and second side views 300b and 300c of the elementary logic gate 300 with reference to the device of FIG. 2. The values of d1 and d2 represent the distances between two racetrack elements lying in the same plane, while d3 represents the distance between two racetrack elements lying in different planes. The elements 391 identify restrictions (pinning sites) of the magnetization domains, which improve the stability of the domains of the racetrack elements. This ensures better confinement of the information bits within the racetrack elements, stably defining the dimensions of the bits themselves. In this embodiment of the invention, the distances d1, d2 and d3 must be sized in such a way as to produce the coupling between the first magnetization regions 103, adapted to operate as input magnetization regions 301, 302e 303, and the second magnetization regions 103a, adapted to operate as output magnetization regions 304, of the elementary logic gate 300, while substantially cancelling the magnetic coupling contribution of the remaining first magnetization regions 103 and/or second magnetization regions 103a in proximity to the second magnetization region 103a adapted to operate as output magnetization region 304.

Other embodiments of the invention may comprise one or more elementary logic gates comprising two or more input magnetization regions and one or more output magnetization regions, magnetically coupled together according to a predetermined weight (or intensity) dependent on their geometric conformation and/or their respective positions, so as to improve the functionality and processing performance of said device 200.

FIG. 3b shows a truth table 350 of the elementary logic gate 300 of FIG. 3a, wherein the information stored in the output magnetization region 304 depends on the information stored in the input magnetization regions 301, 302 and 303. Said logic gate 300 comprises, therefore, three inputs and one output. It is possible to observe that, as a function of the logic value assumed by the input region 301, the elementary logic gate 300 may operate either as a NOR gate (301 equal to “0”) or as a NAND gate (301 equal to “1”) having, as inputs, the two remaining inputs 302 and 303. The input element 301 operates as a programmable input of the elementary logic gate 300, so that the implemented NOR or NAND function can be changed during the execution of an algorithm; this advantageously permits the implementation of a complete set of Boolean operators in the device 200, i.e., the execution of all possible Boolean functions.

In the present embodiment of the invention, the device 200 is made up of three input racetrack elements 210a, 210b and 210c and one output racetrack element 220, which, as previously described, stores the result of the operation. The output racetrack element 220 has at least one output magnetization region 304, preferably a plurality of output magnetization regions 304, e.g., positioned in an alternate manner within the structure, thus providing a plurality of elementary logic gates 300. The input racetrack elements 210a, 210b and 210c and the output racetrack element 220 are adapted to move, in an independent manner, the data stored in said first magnetization regions 103 and/or in said second magnetization regions 103a. This advantageously allows for parallel processing of the data in the plurality of output magnetization regions 304. In another embodiment of the invention, said device 200 may comprise a plurality of input racetrack elements and a plurality of output racetrack elements, wherein said pluralities of input and output racetrack elements are adapted to constitute a plurality of elementary logic gates, these being adapted to process the data stored within said plurality of input racetrack elements in parallel and to store the result into said plurality of output racetrack elements.

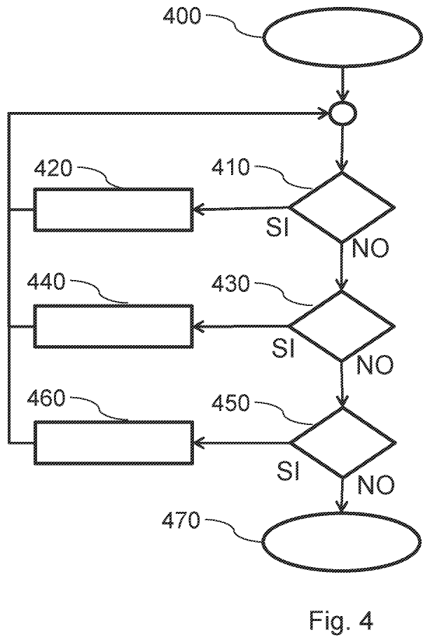

With reference to FIG. 4, the following will describe an exemplary method for storing and processing data in a device 200 according to the embodiment of the invention shown in FIG. 2, wherein the control unit 250 controls the input racetrack elements 210a, 210b and 210c and the output racetrack element 220 in order to execute all the operations necessary for writing, reading and processing the data stored in the device 200.

At step 400, a phase of initializing the device 200 is carried out in order to bring it into a running condition. In this step, for example, the control unit 250 verifies the operating state of the device 200 and/or of the input racetrack elements 210a, 210b and 210c and the output racetrack element 220.

At step 410, the control unit 250 verifies if it is necessary to execute a phase of writing data into the device 200, e.g., following interaction with another device, such as, for example, a processor external to the device 200. If so, the control unit 250 will execute step 420, otherwise it will execute step 430.

At step 420, the control unit 250 executes all the operations necessary for carrying out the phase of writing the data into the device 200. The data may come, for example, from external data lines connected to the device 200. During this step, the control unit 250 may, for example, magnetize, by means of one or more write elements 106, the first magnetization regions 103 of the input racetrack elements 210a, 210b and 210c according to a predefined binary encoding. The control unit 250 may, for example, independently manage the spin-polarized electric currents 108 of each input racetrack element 210a, 210b and 210c in such a way as to shift (slide) the information along the memory elements 120, so that one or more write elements 106 can write the data.

At step 430, the control unit 250 verifies if it is necessary to execute a phase of processing the data in the device 200, e.g., following interaction with another device, such as, for example, a processor external to the device 200. If so, the control unit 250 will execute step 440, otherwise it will execute step 450.

At step 440, the control unit 250 executes all the operations necessary for carrying out the phase of processing the data in the device 200. During this processing phase, the second magnetization regions 103a of said output racetrack element 220 are made to switch from said first direction 115 of the magnetization vector to the opposite one 116, or vice versa, based on the magnetic coupling of at least two of said first magnetization regions 103 of said input racetrack elements 210a, 210b, 210c, wherein the output racetrack element 220 and the input racetrack elements 210a, 210b, 210c constitute at least one elementary logic gate 300 of the device 200.

The input binary information of the elementary logic gate 300 is represented by the respective magnetization vectors of two or more input magnetization regions 301, 302, 303. The output binary information of the elementary logic gate 300 is represented by the magnetization vector of one or more output magnetization regions 304.

The switching of the magnetization vector from a logic value to its opposite in the output magnetization region 304 is obtained by adding up the contribution of each magnetization vector of two or more input magnetization regions 301, 302, 303, respectively. The switching of the magnetization vector from a logic value to its opposite in the output magnetization region 304 can be triggered by a suitably generated magnetic coupling contribution of an external magnetic field (Hₑₓₜ).

For example, if the resulting magnetic coupling value exceeds a predefined critical value H_{c}, then the magnetization vector will switch from a logic value to its opposite; otherwise, no switching of the magnetization vector in the output magnetization region 304 will occur.

During said processing phase, the data stored in said first magnetization regions 103 and/or said second magnetization regions 103a are shifted independently in said input racetrack elements 210a, 210b, 210c and output racetrack element 220. For example, the control unit 250 may control, in an independent manner, the spin-polarized electric currents 108 of each input racetrack element 210a, 210b and 210c in such a way as to shift (slide) the information along the memory elements 120. Advantageously, this makes it possible to substantially modify the information, e.g., the bit values, contained in the input magnetization regions 301, 302, 303 of each elementary logic gate 300 of the device 200 in an instantaneous manner, thereby obtaining a high degree of parallelism of the logic operations, such as, for example, NOR or NAND operations. The result of the logic operations is processed simultaneously (in parallel) in the output magnetization regions 304 of each elementary logic gate 300 of the device 200. Because of this, it is advantageously no longer necessary to transport the data outside the memory element via connections (data lines), process them externally, and then store them again into the memory element, thus advantageously overcoming the limitations of Von Neumann's computational machines.

At step 450, the control unit 250 verifies if it is necessary to execute a phase of reading the data in the device 200, e.g., following interaction with another device, such as, for example, a processor external to the device 200. If so, the control unit 250 will execute step 460, otherwise it will execute step 470.

At step 460, the control unit 250 executes all the operations necessary for carrying out the phase of reading the data in the device 200. The data may be read and sent to other devices external to the device 200, such as, for example, a screen of a television apparatus, e.g., via data lines connected to the device 200 and to the external device. During this step, the control unit 250 may, for example, activate the read elements 107 of the input racetrack elements 210a, 210b and 210c and/or of the output racetrack element 220 for reading the information, e.g., binary information, stored as magnetization states of the first magnetization regions 103 and/or of the second magnetization regions 103a. The control unit 250 may, for example, independently manage the spin-polarized electric currents 108 of each input racetrack element 210a, 210b and 210c in such a way as to shift (slide) the information along the memory elements 120, so that one or more read elements 107 can read the data.

At step 450, the control unit 250 executes all the operations necessary for terminating the write, read and processing operations on the data stored in the device 200. During this step, the control unit 250 may signal the inoperative state of the device 200 to another device, such as, for example, a processor external to the device 200.

The advantages of the present invention are apparent from the above description.

The device and the method for data storage and processing of the present invention advantageously allow processing the data stored within the device by means of the magnetic coupling between first and second magnetization regions of the racetrack elements of the device itself.

A further advantage of the device and method for data storage and processing of the present invention lies in the high level of parallelism of logic operations, such as NOR or NAND operations. Advantageously, the result of the logic operations is processed simultaneously (in parallel) in the output magnetization regions of each elementary logic gate of the device.

Another advantage of the device and method for data storage and processing of the present invention lies in the fact that the limitations of Von Neumann's computational machines are overcome. In fact, the device and the method for data storage and processing of the present invention advantageously avoid the need for transporting the data outside the array of memory cells via connections (data lines), processing them, and then storing them again into the array of memory cells.

A further advantage of the device and method for data storage and processing of the present invention lies in the fact that fully magnetic or transistor-based hybrid circuits can be implemented, e.g., by interfacing the device according to the present invention with other devices based on different technologies.

Of course, without prejudice to the principle of the present invention, the forms of embodiment and the implementation details may be extensively varied from those described and illustrated herein merely by way of non-limiting example, without however departing from the protection scope of the present invention as set out in the appended claims.

1. A device for data storage and processing, comprising:
at least two input racetrack elements comprising a plurality of first magnetization regions;
at least one output racetrack element comprising a plurality of second magnetization regions, wherein a magnetization vector is adapted to switch from a first direction to the opposite one, or vice versa, by means of a magnetic field of reduced intensity compared with a magnetic field required to produce a similar switching of a magnetization vector of the first magnetization region,
wherein said input racetrack elements and output racetrack element are configured in such a way as to constitute at least one elementary logic gate, wherein at least two of said first magnetization regions are magnetically coupled to at least one of said second magnetization regions.

2. The device according to claim 1, wherein said at least one elementary logic gate comprises two or more input magnetization regions, for which the respective magnetization vectors represent input binary information of said elementary logic gate, and one or more output magnetization regions, the magnetization vector of which represents output binary information of said elementary logic gate.

3. The device according to claim 2, wherein said first magnetization regions correspond to said two or more input magnetization regions, and wherein said second magnetization region corresponds to said output magnetization region, such correspondences being defined according to a predefined magnetic coupling scheme.

4. The device according to claim 2, wherein said two or more input magnetization regions and said output magnetization region are magnetically coupled together according to a predetermined weight dependent on their geometric conformation and/or their respective positions.

5. The device according to claim 2, wherein the switching of the magnetization vector in the output magnetization region is obtained by adding up the contribution of each magnetization vector of said two or more input magnetization regions, respectively, and wherein the switching of the magnetization vector in the output magnetization region is triggered by a magnetic coupling contribution of an external magnetic field (Hₑₓₜ).

6. The device according to claim 5, wherein the switching of the magnetization vector in the output magnetization region occurs if the resulting magnetic coupling contribution exceeds a predefined critical value (H_{c}).

7. The device according to claim 1, wherein said input racetrack elements and output racetrack element are adapted to move the data stored in said first magnetization regions and/or said second magnetization regions in an independent manner.

8. A method for storing and processing data in a device, said device comprising:
at least two input racetrack elements comprising a plurality of first magnetization regions;
at least one output racetrack element comprising a plurality of second magnetization regions, wherein a magnetization vector is adapted to switch from a first direction to the opposite one, or vice versa, by means of a magnetic field of reduced intensity compared with a magnetic field required to produce a similar switching of a magnetization vector of the first magnetization region,
said method comprising a step of processing the data in said device,
wherein during said processing step, said second magnetization regions of said output racetrack element are made to switch from said first direction of the magnetization vector to the opposite one, or vice versa, based on the magnetic coupling of at least two of said first magnetization regions of said input racetrack elements, wherein said output racetrack element and said input racetrack elements constitute at least one elementary logic gate of said device.

9. The method according to claim 8, wherein, during said processing step, the input binary information of said elementary logic gate is represented by the respective magnetization vectors of two or more input magnetization regions, and wherein the output binary information of said elementary logic gate is represented by the magnetization vector of one or more output magnetization regions.

10. The method according to claim 9, wherein, during said processing step, the switching of the magnetization vector in the output magnetization region is obtained by adding up the contribution of each magnetization vector of said two or more input magnetization regions, respectively, and wherein the switching of the magnetization vector in the output magnetization region is triggered by a magnetic coupling contribution of an external magnetic field (Hₑₓₜ).

11. The method according to claim 10, wherein, during said processing step, the switching of the magnetization vector in the output magnetization region occurs if the resulting magnetic coupling contribution exceeds a predefined critical value (H_{c}).

12. The method according to claim 8, wherein, during said processing step, the data stored in said first magnetization regions and/or said second magnetization regions are moved independently in said input racetrack elements and output racetrack element.
